(19) United States
(12) Patent Application Publication
(10) Pub. No.: US 2026/0371946 A1
(43) Pub. Date: Nov. 19, 2026

(54) METHOD AND DEVICE FOR BONDING SUBSTRATES

(71) Applicant: EV Group E. Thallner GmbH, St. Florian am Inn (AT)

(72) Inventor: Friedrich Paul Lindner, St. Florian am Inn (AT)

(73) Assignee: EV Group E. Thallner GmbH, St. Florian am Inn (AT)

(21) Appl. No.: 19/126,522

(22) PCT Filed: Nov. 18, 2022
(86) PCT No.: PCT/EP2022/082396

§ 371 Date: May 1, 2025

(51) Int. Cl. H10P 10/00

(52) U.S. Cl. CPC H10P 10/128

(57) ABSTRACT

Method and device for the bonding of substrates. See in this regard FIG. 1a.

### FIELD OF THE INVENTION

The present invention relates to a method and a device for the bonding of substrates, in particular wafers.

### BACKGROUND OF THE INVENTION

During bonding, substrates are aligned with one another, contacted with one another and bonded with one another. For the alignment, the substrates are each held in a substrate mounting device, in particular a vacuum substrate holder, and the substrate surfaces to be bonded are exactly aligned with one another before the bonding. A bond as distortion and expansion free as possible over the entire surface is thereby to be produced.

In the prior art, the upper substrate and the lower substrate are loaded in the bonding orientation, so that the bonding side of the upper substrate and the bonding side of the lower substrate are already directed towards one another before the bonding. This has the advantage that the bonding devices occupy less space, since the upper substrate holder does not have to be turned, rotated or moved, but the substrates to be bonded are produced with different stresses in the respective substrates due to the different acting adhesive forces at the upper and at the lower substrate holder.

The upper and the lower substrate are loaded in the bonding orientation in publication U.S. Pat. No. 9,613,840 B2. The upper substrate is deformed by means of deformation means, in particular a mechanical pin, wherein the deformation means act, in particular due to their shape, on the side facing away from the bonding side. The beginning of the contacting is influenced by the central deformation of the upper substrate with the pin, whereas after the contacting the upper substrate is released and automatically bonds on account of its pre-stressing with the substrate lying opposite.

In U.S. Pat. No. 9,613,840 B2, at least one substrate is no longer fixed on the mounting device during the bonding process. Furthermore, the upper and the lower mounting devices are not designed identically on account of the different embodiments and thus produce different stress patterns in the substrate on account of the loading or fixing.

Fixing means for the at least partial pre-fixing of the aligned substrate on the carrier substrate are provided in U.S. Pat. No. 8,918,989 B2. The two substrates are loaded above one another in the bonding orientation one after the other. Spacers for maintaining a distance between the substrate and the carrier substrate are used during the alignment, before a force-regulated actuator acting in the centre acts on the substrate stack for the fixing of the substrates. In U.S. Pat. No. 8,918,989 B2, the bonding or pre-bonding takes place completely without prior fixing of the upper substrate on an upper mounting device.

In publication U.S. Pat. No. 6,383,890 B2, the two substrates are loaded from above. By rotation through 180° of the upper mounting device mounted in a swivelling manner, the two substrates are positioned in the bonding orientation opposite one another in parallel for the bonding. A pin penetrates the upper mounting device and starts the bonding process by centric curving of the upper substrate. The upper substrate is thereby released from the fixing. The symmetrical embodiment of all the features and in particular the fixing elements of the upper and lower substrate mounting devices, in particular of the loading pins of the upper and lower substrate mounting devices, is not provided. In addition, different holding forces or fixing forces are provided.

In publication WO 2015/183197 A1, the upper substrate mounting device is rotated through 180° about its own axis for the bonding. The upper substrate mounting device is moved between the substrate loading position and a substrate bonding position. An advantage here is easier control of the alignment of the substrate provided with structures on the mounting device from the free upper side.

The symmetrical embodiment of all the features of the upper and lower substrate mounting devices is not provided, since the latter are constituted differently on account of the design of the device. In addition, different holding forces are provided in different patterns.

The substrates to be bonded, in particular wafers, are often structured and coated with up to several layers of different materials. These preprocessing steps produce mechanical stresses, which can warp the wafer in its free form. This warping appears for example in the form of a tendency to warpage, curvatures, distortions and/or local deformations. As soon as one of the substrates to be bonded is not fixed or no longer fixed on a substrate mounting device during the bonding process, a part of this stress is incorporated into the bonding interface as a distortion.

The crystalline structure of the substrate material also determines whether properties are isotropic or anisotropic and can thus have an influence on the bonding process. The mechanical properties of silicon (Si) are for example anisotropic. Monocrystalline silicon has a different modulus of elasticity (E-modulus) in different directions. This differing rigidity causes a generated bonding wave to propagate at a different rate. The differences in rigidity also have a strong effect when the substrate, in particular the upper substrate, is released during bonding from the fixing of the substrate mounting device. Due to the direction dependence of the E-modulus, other mechanical properties, in particular expansions, are also direction-dependent.

For several years, substrates have been bonded together by so-called bonding processes in the semiconductor industry. Before the bonding, these substrates must be aligned as accurately as possible with one another, wherein deviations in the nanometre region now play a part. The alignment of the substrates usually takes place by means of alignment marks. Apart from the alignment marks, other, in particular functional elements can also be present on the substrates, which also have to be aligned with one another during the bonding process.

One of the greatest challenges in bonding consists in the bonding process itself, i.e. during the bond initiation up to the complete contacting of the contact surfaces of the substrates. The alignment of the two substrates with one another can still change decisively with respect to the previous alignment. If the two substrate surfaces are first bonded together, a separation is in fact theoretically possible again, but associated with high costs and susceptibility to errors. There are a plurality of methods and systems in the prior art, with the aid of which an attempt can be made to influence the bonding process.

Stress patterns can lead to distortions and susceptibility to errors in the bonding process. The substrates to be bonded, in particular wafers, are often structured and coated with up to several layers of different materials. These preprocessing steps produce mechanical stresses, which can warp the wafer in its free form. Apart from mechanical stresses arising from preprocessing steps, further stress patterns can arise during the loading of the substrates. The components of the mounting device, which have an influence on the substrate form and lead to a loading stress, include in particular the loading pins and the fixing and supporting elements as well as further surface features of the mounting device.

A part of this stress is then incorporated as a distortion in the bonding interface during bonding. Stresses can relax either due to an additional defect formation, can mutually offset on another or remain as a residual stress in the bonded stack.

The residual stress has a strong effect especially with thin substrates or with thin substrates stacks. Back-thinned substrates have to be brought back to the original, preferably flat shape and held.

It is the aim of the invention to eliminate at least partially, in particular completely eliminate the drawbacks listed in the prior art. In particular, it is an aim of the invention to specify improved methods and a device for bonding. Furthermore, it is an aim of the invention to produce a bonded substrate stack with minimal residual stress.

### SUMMARY OF THE INVENTION

The present problem is solved with the features of the coordinated claims. Advantageous developments of the invention are given in the sub-claims. All combinations of at least two features stated in the description, in the claims and/or the drawings also fall within the scope of the invention. In the case of stated value ranges, values lying within the stated limits should also be deemed to be disclosed as limiting values and can be claimed in any combination.

Surprisingly, it has been shown that the bonding result can be improved if, in addition to the mechanical stresses which have already been produced in the substrate in preprocessing steps, new stress patterns caused by design features of the substrate mounting device, which come into direct contact with the substrate, as well as for example in the substrate loading process of the substrates onto the substrate mounting device, are compensated for or prevented. The stress patterns in the prior art are different in the upper and in the lower substrate on account of different effects. For example, different stress patterns are produced in the substrates to be bonded on account of the different embodiment of the upper and the lower substrate mounting device, in particular the substrate holder surface, the fixing elements and the holding forces.

If a force, in particular the gravitational force, acts on the substrates, which lie on loading pins or structures of the holding surface, an asymmetrical deformation arises. This asymmetrical deformation is still present during the contact between the two substrates and/or during the bonding process and leads to an asymmetrical propagation of the bonding wave front and thus to an undesired run-out effect.

Loading of the upper and the lower substrate in the bonding orientation also necessarily leads to different stress patterns, which can also be integrated into the bond interface as a distortion, in particular if the different asymmetrical stress patterns cannot subsequently be mutually removed.

The method and the device for the bonding in particular improve the bonding result by the proposed combinations of features.

Accordingly, the invention relates to a method for the bonding of substrates with the following steps, in particular with the following sequence: i) provision of a first substrate on a first substrate holder surface of a first substrate holder and a second substrate on a second substrate holder surface of a second substrate holder, ii) fixing of the first substrate on the first substrate holder and the second substrate on the second substrate holder in a loading state, iii) positioning of the second substrate holder relative to the first substrate holder in a bonding position, so that the first substrate and the second substrate are facing one another with surfaces to be bonded, iv) bonding of the first substrate with the second substrate, wherein in the loading state the first substrate holder surface and the second substrate holder surface are arranged at an identical angle relative to the gravitational force, and wherein in the loading state the first substrate holder surface and the second substrate holder surface are aligned in the same direction relative to the gravitational force and wherein, in the fixing of the first substrate and the second substrate, identical holding forces are exerted respectively on the first substrate and the second substrate.

In other words, two substrates are provided under identical gravitational conditions on the substrate holders aligned identically relative to the gravitational force and identical holding forces are provided on the substrates for the fixing. An identical stress can thus be produced particularly advantageously in the substrates, which has an advantageous effect on the bonding result. The symmetrical arrangement of the fixing elements on the substrate holders relative to the bonding interface in the bonding position are particularly preferred. In this positioning, the substrates or the substrate holder surfaces are particularly preferably positioned symmetrical to one another and parallel to one another, so that the surfaces to be bonded are facing one another. Symmetrical positioning or alignment means that the fixing locations, holding forces at the fixing locations and supporting surfaces of the substrate holders are congruent or are symmetrical through the mirroring and the plane spanned between the substrates. In other words, all the features are aligned which have an influence on the stress in the substrates in the loading state.

The first substrate and the second substrate are preferably identically dimensioned. In particular, the substrates have the same weight. The first substrate holder surface is constituted symmetrical to the second substrate holder surface, in particular axis-symmetrical. The substrate holder surfaces preferably correspond, such that in the loading state the supporting surfaces of the respective substrate holding surfaces are arranged symmetrically to one another and the supporting surfaces lying opposite are aligned during the bonding. The substrate holder surfaces are in particular the surfaces of the substrate holders on which the substrates lie. The substrate holder surfaces comprise for example loading pins, elevations or full surfaces with recesses for fixing means.

In the loading state, the substrate holders or the substrate holder surfaces and thus the substrates are arranged identically relative to the acting force of gravity. The substrate holder surfaces are aligned in the same direction relative to the force of gravity. For example, both substrate holder surfaces are aligned upwards or downwards. In the loading state, the substrates are not loaded from above and below, but both identically, so that the force of gravity acts identically at the time of loading and also, with the application of the identical holding forces, the identical stress, in particular the identical stress pattern, acts on both substrates.

The surfaces of the substrates to be bonded do not lie on the substrate holder surface, but point away from the substrate holders. The substrate holders are preferably both vertical or horizontal to the force of gravity. The substrate holders preferably arranged beside one another have the same angle relative to the force of gravity in the loading state. The slightly different force of gravity due to the offset arrangement and a slightly different distance to the centre of the earth can be overlooked.

In the fixing of the substrates, identically acting and identical holding forces are provided at the substrates. A corresponding stress pattern can thus advantageously be produced in the substrates, which improves the bonding result. The holding forces are preferably also retained with the transfer into the bonding position.

The positioning take place arbitrarily and can include a movement of both substrate holders in all directions.

During the bonding of substrates or substrate stacks, the substrates to be bonded are loaded, so to speak, with minimal invasion onto corresponding mounting devices in an identical alignment to the force of gravity and are held by means of identical or symmetrical holding forces acting on the two substrates. Different holding forces are usually provided, since substrates to be bonded after the positioning at one point in time lie on the lower substrate holder and have to be held at the upper one. At the upper substrate holder, the greater holding force usually acts, because in addition the weight of the fixed upper substrate has to be compensated for.

The symmetry preferably also relates to all further components of the substrate holder which can have an influence on the stress in the substrates (supporting surfaces, nature of the fixing elements, alignment marks, tubes, etc.). An axis-symmetrical arrangement of all the components is preferable.

In a preferred embodiment of the method for bonding, provision is made such that in the loading state the first substrate lies on the first substrate holder surface and the second substrate on the second substrate holder surface. “Lies on” is understood to mean that the first substrate and the second substrate each lie due to the intrinsic weight on the likewise identically aligned substrate holder surfaces and do not theoretically have to be fixed. In other words, the surfaces to be bonded both lie aligned against the force of gravity, whilst rear sides of the substrates lie on the substrate holder surfaces. A particularly advantageous and stress-free loading can thus be carried out.

In a preferred embodiment of the method for bonding, provision is made such that the angle is a vertical angle. The same angle, at which the substrate holder surfaces are aligned relative to the force of gravity, amounts in other words to 90°. The substrates and the substrate holder surfaces are preferably flat. The substrates are thus also aligned virtually parallel to the weight force and consequently to the centre of the earth. A particularly good bonding result can thus be achieved. Furthermore, slipping of the substrates can be prevented.

In a preferred embodiment of the method for bonding, provision is made such that, during the fixing in the loading state, the identical holding forces each in a pattern corresponding to one another are provided at the first substrate and the second substrate, so that the pattern of the holding forces is aligned in the bonding position. In other words, the substrate surfaces lying opposite one another are congruent with respect to the provided fixing pattern in the bonding positions. Identical holding forces in positions lying precisely opposite one another are thus provided in the bonding position. It is thus ensured that the stresses prevailing in the substrates are positioned identically and of equal size in the bonding position on account of the fixing at the regions of the substrate surfaces lying opposite. The stress distribution in the first substrate is thus aligned with the stress distribution in the second substrate in the bonding position. In the loading state, the holding forces are thus provided for example in an axis-symmetrical arrangement, so that simple swivelling is sufficient for the positioning.

In a preferred embodiment of the method for bonding, provision is made such that the fixing of the first substrate and of the second substrate takes place simultaneously and within the same period. In other words, the holding forces are applied within the same period and take place simultaneously. The increase in the holding force per unit of time is preferably also identical at the same points. A still better bonding result can thus be achieved.

In a preferred embodiment of the method for bonding, provision is made such that the positioning comprises swivelling of the second substrate holder through 180°. Swivelling of the second substrate holder preferably constitutes the positioning, so that the first substrate holder does not have to be moved. After the positioning or the transfer into the bonding position, an approach of the substrate holders is possibly necessary. By the swivelling of the second substrate holder of 180° about the axis of symmetry, a particularly easy and fault-free transfer into the bonding position can advantageously be brought about. After the swivelling, the second substrate holder is preferably aligned precisely perpendicular to the direction in the loading state.

“Towards one another” means that the substrate holder surfaces are aligned facing one another. An additional movement for the initial contacting for the bonding then takes place in particular by an approach of the first substrate holder surface and the second substrate holder surface or the first substrate holder and the second substrate holder. The identical holding forces are preferably retained and the corresponding patterns are merely moved farther towards one another. The alignment preferably takes place only by the swivelling.

In a further preferred embodiment of the method for bonding, provision is made such that the positioning comprises a swivelling of the first substrate holder and the second substrate holder towards one another each through 90°. The two substrate holders are swivelled along the axis of symmetry or through parallel centre-point axes in the respective centre-point of the substrate holders. In this way, the force of gravity for the first and the second substrate is also the same after the positioning, if the alignment is perpendicular to the force of gravity in the loading state. In the loading state, the first substrate holder surface and the second substrate holder surface are particularly preferably aligned precisely perpendicular to the force of gravity. The bonding result can thus be improved with a two-sided swivelling.

In a preferred embodiment of the method for bonding, provision is made such that the identical holding forces are maintained during the bonding. In this way, the identical holding forces are retained not only in the fixing and in the transfer or positioning into the bonding position, but also maintained thereafter until after completion of the bonding. The residual stresses on account of the loading can thus be compensated for and the bonding result is improved.

Furthermore, the invention relates to a device for the bonding of substrates, at least comprising a first substrate holder with a first substrate holder surface, first fixing means for fixing a first substrate on the first substrate holder surface, a second substrate holder with a second substrate holder surface, second fixing means for fixing a second substrate on the second substrate holder surface, and positioning means for positioning the second substrate holder relative to the first substrate holder, wherein the device can be transferred into a loading state, in which the first substrate holder surface and the second substrate holder surface are arranged at the same angle relative to the force of gravity, wherein in the loading state the first substrate holder surface and the second substrate holder surface are aligned in an identical direction relative to the force of gravity and wherein the first fixing means and the second fixing means are designed to each provide identical holding forces for the fixing in the loading state.

In other words, the first fixing means and the second fixing means act in an identical manner on a first substrate and a second substrate. The device is designed such that the provided holding forces of the first fixing means and the second fixing means are equal in size. The fixing means are particularly preferably constituted to provide the identical holding forces simultaneously and within the same period. The increase per time unit of the holding forces is preferably also identical with the fixing means or the device is designed as such. As a result of the loading in the loading state, an identical stress pattern is produced in both substrates to be bonded. The bonding result is thus unexpectedly improved. The device can comprise a control unit, which is designed to provide the respective conditions in the loading state. The further advantages and features of the method described above for the bonding should also apply analogously to the device.

In a preferred embodiment of the device for the bonding of substrates, provision is made so that the device is designed such that in the loading state the first substrate holder surface and the second substrate holder surface are arranged offset in parallel beside one another. In particular, a centre-point of the substrate holder surfaces is offset in respect of the direction. Preferably, the first substrate holder surface and the second substrate holder surface are arranged offset beside one another in the loading state, in such a way that they are not aligned, but have a distance from one another relative to the same angle. Particularly uniform loading can thus take place and the bonding result can be improved.

In a preferred embodiment of the device for the bonding of substrates, provision is made such that the second substrate holder can be swivelled out of the loading state into a bonding position. The bonding position is characterised in particular in that the substrate holder surfaces are facing one another and are aligned parallel to one another, so that bonding can take place solely by an approach. In other words, the substrates are already aligned in the bonding position and the positioning is completed. Approach means can be provided for this. By the simple swiveling into the bonding position out of the loading state after fixing by the fixing means, the bonding result can advantageously be improved. The embodiment of the device as a flip-bonder is preferred.

In a preferred embodiment of the device for the bonding of substrates, provision is made such that the positioning means comprise a swivelling link. Positioning of the substrate holders can thus take place particularly easily and precisely about the swivelling axis, so that the bonding result is improved.

In a preferred embodiment of the device for the bonding of substrates, provision is made such that the second fixing means are arranged axis-symmetrically to the first fixing means in the loading state. In other words, a position results after the loading, in which the stress patterns of the substrates are aligned or the substrate holder surfaces and the fixing elements are aligned, i.e. in the bonding position. All the features and components of the two substrate holders influencing the stress in the substrates are very particularly preferably axis-symmetrical.

The axial symmetry is preferably defined by a mirror axis, which runs through the swivelling link. In other words, in the loading state the first substrate holder surface and the second substrate holder surface, in particular the first and the second fixing means, are symmetrical in respect of the swivelling axis, so that the arrangement of the fixing elements are aligned with one another after the swivelling into the bonding position. If the first substrate holder and the second substrate holder are arranged offset beside one another at different heights in the loading state, the mirror axis runs through the plane which is spanned by the swivelling axis at the specific angle of the substrate holders in the loading state. In any case, the pattern of the fixing elements is constituted corresponding to one another, so that after the transfer into the bonding state, the substrate holder surfaces lying opposite one another have an identical and aligned stress pattern on account of the loading.

In a preferred embodiment of the device for the bonding of substrates, provision is made such that the first fixing means and the second fixing means are electrostatic fixing means. Particularly preferably, the first and second fixing means are engaged in the substrate holder surfaces. The corresponding engagement grooves are also particularly preferably arranged in symmetrical patterns like the first and second fixing means. In the case of a full-surface embodiment of the electrostatic fixing means, the dimensions and arrangements are also aligned in the bonding position. In another embodiment, the fixing means are vacuum tracks, wherein the arrangement and other formation are also constituted congruent or corresponding in the bonding position.

In a preferred embodiment of the device for the bonding of substrates, provision is made such that in the bonding position the first substrate holder and the second substrate holder constitute a fluidically tight bonding chamber. A bonding chamber can thus be formed between the first substrate holder and the second substrate holder by swivelling and possibly an approach. The substrates are arranged inside the bonding chamber. Bonding can thus advantageously take place in a protected space, as a result of which the bonding result is improved. In addition, with a particularly preferably fluidically tight bonding chamber, a vacuum can be adjusted before the bonding in the bonding chamber or a fluid can be introduced.

In a preferred embodiment of the device for the alignment of substrates, provision is made such that the first fixing means and the second fixing means are constituted to provide the identical holding forces at least until the transfer into the bonding position. The identical holding forces are particularly preferably provided by the fixing means until immediately after the bonding of the first substrate with the second substrate. In this way, the stresses in the pattern can advantageously be kept the same in the first and the second substrate, at least those which are produced in the loading state on account of the loading/fixing. Stresses can thus be compensated for and the bonding result can be improved.

A particularly important aspect of the present invention is that both substrates are mounted in an identical manner on symmetrically constituted mounting devices before the contacting or the bonding, so that the substrates are contacted or bonded with respectively corresponding stress patterns. The loading of the two substrates is carried out in particular with an identical influence of gravity, for example both from above. All the features of the mounting devices, which can indirectly have an influence on the substrate shape, are constituted symmetrically for the first substrate and for the second substrate, preferably within the same amount of time, particularly preferably simultaneously, so that the first and the second substrate exhibit identical stress patterns opposite one another, caused by the mounting devices, before the bonding. At least one of the mounting device is preferably mounted in a swivelling manner. For this purpose, the fixing or the holding force is provided such that the surfaces to be bonded have the same stress patterns to one another after the swivelling. The two substrates preferably remain fixed on the holding device during the bonding. The influence of the loading stress is minimised by the symmetrical embodiment of the mounting devices, so that the residual stress is minimised after the bonding. Further distortions are minimised by the fixing of at least one of the substrates, preferably both substrates, during the bonding.

The method for bonding leads to a reduction in stress patterns, which are incorporated as a distortion into the bonding interface during bonding. The relaxation of corresponding stress patterns leads to a minimised residual stress even after the release of the substrate stack.

The basis of the idea is that both substrates are mounted on symmetrically constituted mounting devices before the contacting or the bonding, so that the stress on the substrate caused by the mounting and loading onto the mounting device is minimised and the substrates are contacted or bonded with respectively corresponding stress patterns. In the following text, the words stress, loading or stressing are used synonymously. A further important aspect is that the substrates remain fixed during the bonding after the contacting on the mounting devices, so that distortions are minimised by the fact that corresponding stress patterns are mutually eliminated as far as possible and a reduction in the residual stress is thus achieved.

A method and a device are proposed for carrying out the bonding of a first substrate with a second substrate with contact surfaces of the substrates facing one another with the following steps, in particular the following sequence:
mounting of the first substrate on a first mounting surface of a first mounting device, wherein the loading takes place from above,
mounting of the second substrate on a second mounting surface of a second mounting device, wherein the loading takes place from above,
fastening of the substrates to the mounting surfaces by fixing elements,
rotation of the swivel-mounted first and/or second mounting device, so that both the bonding surfaces to be bonded are aligned with one another and symmetrically,
alignment of the substrates,
approach of the two substrates and bonding by contacting,
   wherein the first and second mounting device have a symmetrical embodiment of all the components and wherein, after the contacting, the substrates remain fixed on the first and/or second mounting device during the bonding.

The two mounting devices or substrate holders can be rotated around an arbitrary axis and then brought through X/Y rotation into an adjusted, symmetrical position.

The loading of the two substrates in the symmetrical orientation with an identical influence of gravity on the first and on the second mounting device is decisive. For bonding, preferably either one mounting device with a substrate is swivelled upside down through 180°, or both mounting devices are rotated with a substrate through 90° with respect to one another, so that they also meet symmetrically.

The components of the first and second mounting device, which are formed symmetrically with respect to the tilting axis and/or the mirror axis between the first and second mounting device, include in particular the loading pins and the fixing and support elements as well as further possible characteristic surface features of the mounting device.

The loading pins, preferably three loading pins, are arranged in a circular manner symmetrically on an identical radius on both mounting devices. If the substrates are each loaded onto the first and second mounting device from above onto the loading pins, the substrates bend for example according to the effect of the force of gravity. After mounting of the substrates on the mounting surface of the mounting devices, the loading stress or the stress patterns remain on the fixed substrate. Due to the symmetry of the components of the mounting devices, the stress patterns on the first and second substrate are also symmetrical. The effect of gravity on the loading stress of the substrates is thus minimised or preferably eliminated, since the effects on both substrates after contacting can be removed by the symmetry.

The stress patterns of the two substrates are thus symmetrical along the bonding interface. After the release of the bonded substrate stack, the two substrates can reduce the still present residual stress in the same way due to relaxation, so that remaining stresses are minimised.

### Substrates

The first and/or second substrate is preferably radially symmetrical. Although the substrate can have any diameter, the substrate diameter is in particular 1 inch, 2 inches, 3 inches, 4 inches, 5 inches, 6 inches, 8 inches, 12 inches, 18 inches or greater than 18 inches. The thickness of the first and/or second substrate lies between 1 μm and 2000 μm, preferably between 10 μm and 1500 μm, with greater preference between 100 μm and 1000 μm. In particular embodiments, a substrate can also have a rectangular shape, or at least a shape diverging from the circular shape. Preferably wafers, particularly preferably circular wafers, are used as substrates.

### Mounting Device

The mounting devices enable a reliable and flat support and fixing of the substrates. The fixing takes place for example by applying a vacuum between the substrate and the mounting device, by mechanical clamping, by an electrostatic charge, by other controllable chemical-physical adhesion properties.

Electrostatic mounting devices are preferably used for mounting and holding a substrate. The embodiments of the device for bonding or the bonding device can handle any substrate, irrespective of its diameter.

Electrodes for producing an electrostatic holding force for fixing the substrate are particularly preferably engaged in electrostatic mounting devices. The substrate is fixed on a holding surface or substrate holder surface. The holding surface is a surface of a mounting device, constituted for the substrate fixing and preferably formed flat, which is incorporated as a component in the substrate holder. In the following text, the evenness will be used as a measure for the perfection of a flat surface (mathematically ideal plane).

The evenness denotes the structure of a surface, which is present between two ideal planar surfaces. Spacing of the two planar surfaces defines the tolerance. Deviation from a flat surface arise due to macroscopic and/or microscopic surface defects. These defects can also be defined as waviness and roughness. The waviness of a surface can be described as a periodic rising and falling of the surface, in particular in the millimetre and micrometre range. The roughness, on the other hand, is more of an aperiodic phenomenon in the micrometre and/or nanometre range.

In order to deal with the different deviations from the ideal surface, in the rest of the description the term roughness will be used synonymously for the superposition of all such effects. The roughness is given either as the average roughness, root-mean-squared roughness or averaged roughness depth.

The determined values for the average roughness, the root-mean-squared roughness and the averaged roughness depth differ in general for the same measurement section or measurement area, but lie in the same order of magnitude range. The following numerical value ranges for the roughness are therefore to be understood either as values for the average roughness, the root-mean-squared roughness or for the averaged roughness depth.

In a preferred embodiment, provision is made such that the electrostatic mounting devices or substrate holders with electrostatic fixing means have a holding surface that is constituted particularly flat, in order to press on the substrate electrostatically and to ensure the highly stable holding. The electrostatic attraction brings about a uniform distribution of the holding forces over the entire surface. The evenness of the mounting device is better and/or more precise than the thickness variation and nanotopography of the substrates. The substrates already have mechanical stresses due to preprocessing steps, which could cause a distortion in the non-fixed state.

Substrates with wedge errors do not present a problem for mounting devices in the prior art. Wedge errors can be compensated for. Thickness variations of a higher order are more problematic (for example centre vs. edge, four quadrants, etc.). Substrates with high evenness and curvature demands such as for example reflection masks require holding surfaces with a high degree of evenness, because otherwise errors such as for example image positioning errors and superimposition errors (distortions) arise. To this extent, a means for wedge error compensation is preferred in connection with the device for bonding.

The evenness of the holding surfaces of the electrostatic fixing means is less than 1000 nm, preferably less than 200 nm, still more preferably less than 50 nm, most preferably less than 1 nm (difference between the highest point and the lowest point of the surface or the holding surface).

In particular, nanotopography is an essential parameter for the surface quality. Local (erratic) unevennesses should in particular be avoided. The roughness is less than 100 nm, preferably less than 10 nm, still more preferably less than 1 nm, most preferably less than 1 Å. The roughness is in particular also less than 1 nm/μm change in the evenness, still more preferably less than 1 A/μm change in evenness.

For structures in the nm range and exact overlay, a reproducibility of the evenness of the substrates to be bonded is very important. The holding force of the ultra-flat electrostatic fixing means with a holding surface constituted particularly flat enables a conformal planarisation of the substrates.

Both substrates are preferably loaded from above, i.e. perpendicular to gravitation. The rear side of the substrates is brought into contact with loading pins on the holding surface and fixed by electrostatic forces. The substrates are fixed with high positioning precision and with a high holding force. The electrodes are engaged or embedded particularly preferably relative to the substrate holder surface and can be constituted unipolar or bipolar.

The embodiment of the electrodes is symmetrical relative to the axis of the two substrates or the bond interface.

The loading of the two substrates in a symmetrical orientation or in a direction with an identical influence of gravity on the first and on the second symmetrically constituted substrate holder surface is decisive. For the bonding, a mounting device is swivelled upside down with a substrate through 180° and if required is positioned precisely above the lower mounting device, or both mounting devices are swivelled towards one another with a substrate through 90°, so that they also meet symmetrically.

The components of the first and second mounting device, which are formed symmetrically relative to the tilting axis and/or the mirror axis between the first and second mounting device, include in particular the loading pins and the fixing and support elements as well as further surface features of the mounting device.

If the mounting device or the substrate holder comprises loading pins, holes are necessarily present in the substrate holder surface. The holes, into which the loading pins move or the loading pins themselves, are preferably provided with a seal. The position of the loading pins, the openings of the loading pins, the diameter of the openings of the loading pins, as well as the seals are constituted identically and symmetrically on the two mounting devices. Symmetrical features lie opposite one another after rotation of one mounting device (through 180°) or both mounting devices (through 90°). The mounting devices are constituted axis-symmetrical and/or mirror-symmetrical depending on whether one or both mounting devices are tilted or rotated. If the device for bonding or the bonding device comprises recesses, for example for measurement means, these are also preferably constituted identically and symmetrically on both mounting devices.

Further features such as patterns, structures or a structuring on the holding surface are also particularly preferably constituted identical and symmetrical on both mounting devices.

The surfaces at which the fixing takes place can also be provided with a pattern, grooving, nubs, pins, or any other arbitrary topography or surface structuring. The grooves can for example be formed linear, circular or arbitrarily. Any combination is possible, for example grooves and nubs. The selected topography can further reduce the contact surface, in order to obtain a contact surface as small as possible.

In a preferred embodiment, provision is made such that the ultra-flat electrostatic substrate holder comprises symmetrically constituted grooves, which run over the edge of the substrate in order to prevent an air cushion and “swimming” of the wafer after the loading (before the fixing). The grooves are dimensioned and distributed in such a way as to enable an escape of ambient gases. The grooves are for example microgrooves.

In a preferred embodiment, provision is made such that the electrostatic mounting device comprises symmetrically constituted nubs, in order to reduce the risk of contamination of the rear side of the substrate. The substrate holder surface can then be formed at least in part by the surfaces of the nubs.

The electrostatic attraction not only brings about a uniform distribution of the holding forces over the entire surface, but also a good heat exchange and reduced wear. Electrostatic fixing elements or fixing means are thus preferred. Materials with minimal thermal expansion are preferably selected for the mounting device (thermal invariance).

Apart from the material selection, smoothing of the surfaces is also achieved by machine processing, so that the friction coefficient of the holding surface to the substrate is minimised.

Not only the external features of the first and second mounting device are constituted symmetrically and identically with respect to the tilting axis and/or the mirror axis between the first and second mounting device. The first and the second mounting device are also overall (almost) identical, so that both preferably have the same thickness and are constituted by the same components and materials. A first and second combination, each comprising a substrate and a mounting device or substrate holder, particularly preferably have an identical mechanical rigidity.

The thickness of the mounting device is selected such that the total rigidity of the mounting device together with the substrate is not dominated by the anisotropic Young's modulus (E-modulus) of the substrate.

The preferred ultra-flat electrostatic mounting devices can be used in vacuum, high-vacuum and/or ultra-high vacuum systems. The electrostatic mounting devices can also be used at ambient pressure under a gas atmosphere, in particular an inert gas atmosphere.

In a preferred embodiment, provision is made such that the substrate and/or the mounting device can be moved in at least three degrees of freedom, preferably at least four degrees of freedom, more preferably in at least five degrees of freedom, most preferably in all six degrees of freedom. This enables better mobility of the substrate and/or the mounting device.

The Z-direction or the Z-axis runs in the loading position perpendicular as a surface normal to the holding surface of the mounting device. The X-and Y-directions or the X-and Y-axes run perpendicular to one another and parallel to or in the holding surface of the mounting device.

A rotation about the X-axis is denoted by r, a rotation about the Y-axis by q and a rotation about the Z-axis by j.

In another preferred embodiment, provision is made such that the positioning, fixing and movement system for at least one degree of freedom is constituted with a coarse drive and a fine drive. The latter advantageously enables the exact adjustment of the movements.

In another preferred embodiment, provision is made such that the mounting devices comprise a central control unit and/or regulating unit for the control and/or regulation of movements and/or sequences, in particular the fixing of the substrates and the position of the mounting devices in the loading state. The mounting devices or substrate holders preferably comprise at least one sensor for the measurement of influencing factors, in particular at least one distance and/or position sensor. The sensors are also constituted symmetrically positioned and identically.

### Bonding Device

For the bonding, bonding means are provided for the bonding and/or pre-bonding and/or temporary bonding. The words bonding, pre-bonding and temporary bonding are used synonymously.

All the embodiments of the device for bonding can be operated in a low vacuum, more preferably in a high vacuum, with still greater preference in an ultra-high vacuum, in particular with a pressure of less than 100 mbar, preferably less than 0.1 mbar, with still greater preference less than 0.001 mbar, with still greater preference less than 10e−5 mbar, with utmost preference less than 10e−8 mbar.

The loading of the two substrates in the symmetrical orientation with identical influence of gravity on the first and on the second mounting device or substrate holder is decisive for the device for the bonding. Both substrates to be bonded are preferably loaded from above. Particularly preferably, at least one of the mounting devices is mounted in a swivelling manner. For the bonding, either a mounting device is swivelled upside down with a substrate through 180°, or both mounting devices are rotated with a substrate through 90° towards one another, so that they also meet symmetrically. If a mounting device is swivelled upside down with a substrate through 180°, a rotational movement or a combination of a rotational-translatory movement is conceivable. The mounting devices can be rotated about any axis. The rotation of the mounting device with a substrate through 180° can thus take place about a mirror axis in the X-Y plane of the mounting device or as a rotational movement about a swivelling link.

The device enables a high-precision adjustment of the fixed substrates for an exact alignment. The mounting devices are constituted for the approach and the contacting of the substrates.

### Bonding Processes or Bonding

The substrates are aligned with one another before the bonding process. The alignment preferably takes place by alignment systems and with the aid of alignment marks. After the alignment of the two substrates with one another, contacting in particular takes place.

The step of the contacting of the aligned contact surfaces of the two substrates opposite one another is particularly critical in the bonding of two substrates, since the demand is for increasingly exact adjustment accuracy or offset of less than 50 μm, in particular less than 1 μm, preferably less than 250 nm, still more preferably less than 150 nm, most preferably less than 50 nm. Many influencing factors have to be taken into account with such alignment accuracies.

Errors can arise during the contacting and the placing of the substrates, wherein the errors are cumulative and a reproducible adjustment accuracy thus cannot be met. This can lead to considerable rejects.

In a first preferred embodiment, the two substrates each remain fixed after contacting on the first and second mounting device or the substrate holder during the bonding.

If the two substrates remain fixed to the respective mounting device during the bonding, thickness variation (TTV, total thickness variation) and stress patterns of the substrates have little influence on the bonding result. A parallel, spontaneous (1: 1) bonding of the two substrates fixed on the mounting device is achieved, wherein no deformation of the substrates takes place at the bonding front. The bonding preferably takes place in a high vacuum or in an ultra-high vacuum.

The bonding process consists in particular of a force and/or temperature effect. The bonding force is in particular greater than 0.01 kN, preferably greater than 0.1 kN, still more preferably greater than 1 kN, most preferably greater than 10 KN, with utmost preference greater than 100 kN. The corresponding pressure ranges result by standardisation of the bonding force on the surface of the substrates.

The bonding temperature is in particular less than 200° C., preferably less than 150° C., still more preferably less than 100° C., most preferably less than 50° C., with utmost preference at room temperature.

In a second embodiment, after contacting the second, upper substrate in particular remains fixed on the mounting device during the bonding. If the second, upper substrate remains fixed on the mounting device during the bonding, a smaller deformation of the upper substrate at the bonding front takes place on account of the higher rigidity of the fixed substrate.

In a third embodiment, after contacting the first and/or the second substrate in particular remains fixed on the mounting device during bonding. Distortions are minimised by the fixing of at least one of the substrates during the bonding.

### BRIEF DESCRIPTION OF THE DRAWINGS

Further advantages, features and details of the invention emerge from the following description of preferred examples of embodiment and with the aid of the drawings. They show diagrammatically in:

FIG. 1a a cross-sectional view of a first embodiment of the bonding device,

FIG. 1b a plan view of the first substrate holder and the second substrate holder of a first embodiment of the device according to FIG. 1a,

FIG. 2a a plan view of the first and the second substrate holder of a first embodiment of the device with a first rotation axis A-A,

FIG. 2b a plan view of the first and the second substrate holder of a first embodiment of the device with a second rotation axis B-B,

FIG. 3a a cross-sectional view of a first embodiment of the device with a mechanically constituted hinge in the axis of symmetry, with loading pins of the first and second mounting device in the loading state,

FIG. 3b a cross-sectional view of a first embodiment of the device with a mechanically constituted hinge in the axis of symmetry after loading of the first and second substrate on the loading pins,

FIG. 3c a cross-sectional view of a first embodiment of the device with a mechanically constituted hinge in the axis of symmetry after mounting of the first and second substrate on the first and second substrate holder,

FIG. 4 a cross-sectional view of a device in the loading state and in the bonding position before the bonding of the first and second substrate,

FIG. 5a a cross-sectional view of the device in a first process step of an exemplary method for bonding,

FIG. 5b a cross-sectional view of the device in a second process step,

FIG. 5c a cross-sectional view of the device in third process step,

FIG. 5d a cross-sectional view of the device in fourth process step,

FIG. 5e a cross-sectional view of the device in fifth process step,

FIG. 5f a cross-sectional view of the device in the sixth process step,

FIG. 6a a cross-sectional view of a third embodiment of the device in a first process step,

FIG. 6b a cross-sectional view of a third embodiment of the device in a second process step,

FIG. 6c a cross-sectional view of a third embodiment of the device in third process step,

FIG. 7a a cross-sectional view of a fourth embodiment of the device in a first process step

FIG. 7b a cross-sectional view of a fourth embodiment of the device in a second process step,

FIG. 7c a cross-sectional view of a fourth embodiment of the device in a third process step,

FIG. 8a a cross-sectional view of a fifth embodiment of the device in a first process step, and

FIG. 8b a cross-sectional view of a fifth embodiment of the device in a second process step.

### DETAILED DESCRIPTION OF THE INVENTION

Identical components or components with the identical function are denoted by the same reference numbers in the figures.

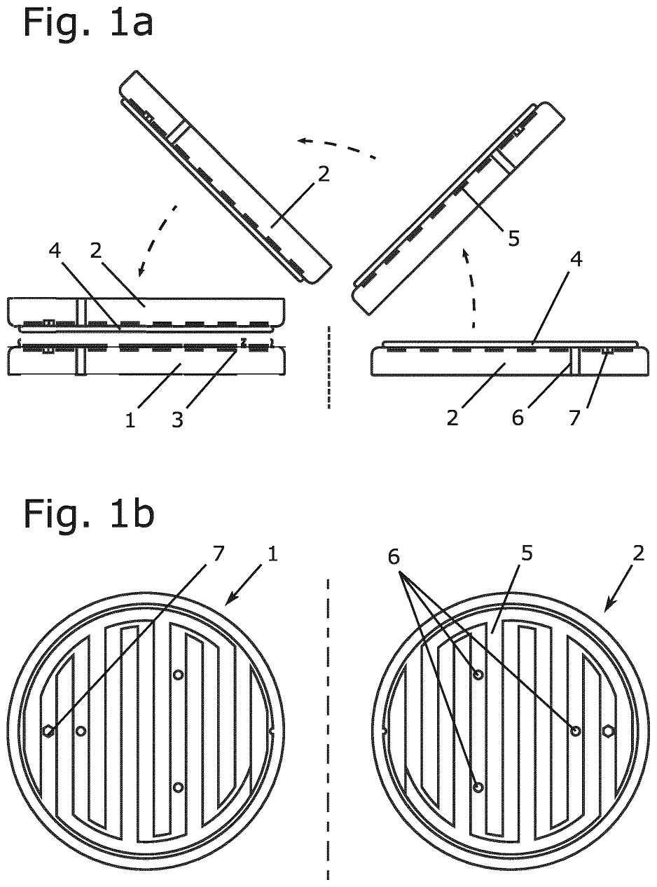

FIG. 1a shows a diagrammatic view, not true to scale, of a view of a cross-section of a first embodiment of first and second mounting devices 1, 2, wherein the movement of second mounting device 2 is represented simplified. The two substrates 3, 4 are loaded from above in an identical manner. The design features of mounting devices 1, 2 such as for example substrate-fixing elements 5, openings for loading pins 6 and further surface features of mounting devices 7 are constituted symmetrically, so that first mounting device 1 and second mounting device 2 lie opposite one another and mirror-symmetrical after rotation of the second mounting device.

Fixing elements 5 serve to fix substrates 3, 4 on mounting device 1, 2. Substrate 3, 4 are fixed electrostatically in a particularly preferred embodiment.

FIG. 1b shows a plan view of the first and second mounting device 1, 2 of a first embodiment of a device according to FIG. 1a.

Both substrates 3, 4 are loaded from above in an identical manner. All features 5, 6, 7 of mounting devices 1, 2, which can have a direct or indirect influence on the shape of the substrates, are constituted symmetrically for first substrate 3 and for second substrate 4, so that first and second substrate 3, 4 have identical stress patterns before bonding, caused by the mounting device. These features include in particular substrate-fixing elements 5, openings for loading pins 6 and further surface features of mounting devices 7 such as for example openings for measuring devices, sensors and lines.

Decisive for the device is the loading of the two substrates 3, 4 in a symmetrical orientation with an identical influence of gravity on firstmounting device 1 and on second mounting device 2. Both substrates 3, 4 are loaded from above onto the respective mounting device (loading position, loading state).

At least one of mounting devices 1, 2 is mounted in a swivelling manner, so that after of the loading of substrates 3, 4, the substrate surfaces to be bonded are brought into the bonding position opposite one another.

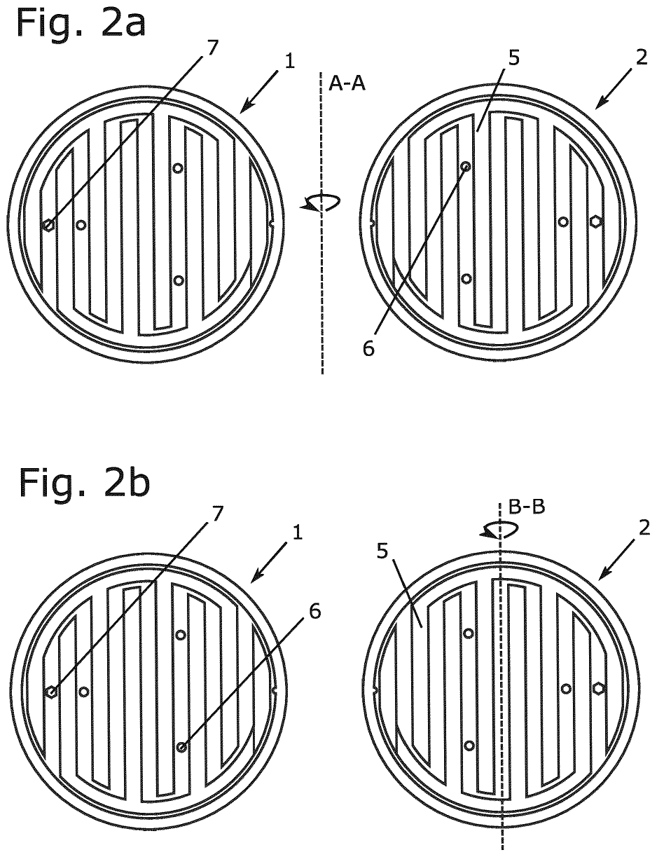

FIG. 2a shows a plan view of first and second mounting device 1, 2 of a second embodiment of a device with a first swivelling axis A-A. In this first embodiment according to FIG. 2a, a second mounting device 2 is moved relative to first mounting device 1 by a rotational movement about a swivelling link (10, not represented), with swivelling axis A-A.

The loading pins and their openings 6 in the holding surfaces of mounting devices 1, 2 are arranged symmetrically on the identical radius on both mounting devices 1, 2.

FIG. 2b shows a plan view of first and second mounting device 1, 2 of a second embodiment of a device with a second rotation axis B-B.

For bonding, either a mounting device with a substrate is swivelled upside down through 180° (axis A-A or B-B), or both mounting devices are rotated towards one another with a substrate through 90°, so that they also meet symmetrically. If a mounting device with a substrate is rotated upside down through 180°, a rotational movement or a combination of a rotational-translatory movement is conceivable. Mounting devices 1, 2 can be rotated about an arbitrary axis. The rotation of the mounting device with a substrate through 180° can thus take place about a mirror axis in the X-Y plane of the mounting device or as a rotational movement about a swivelling link.

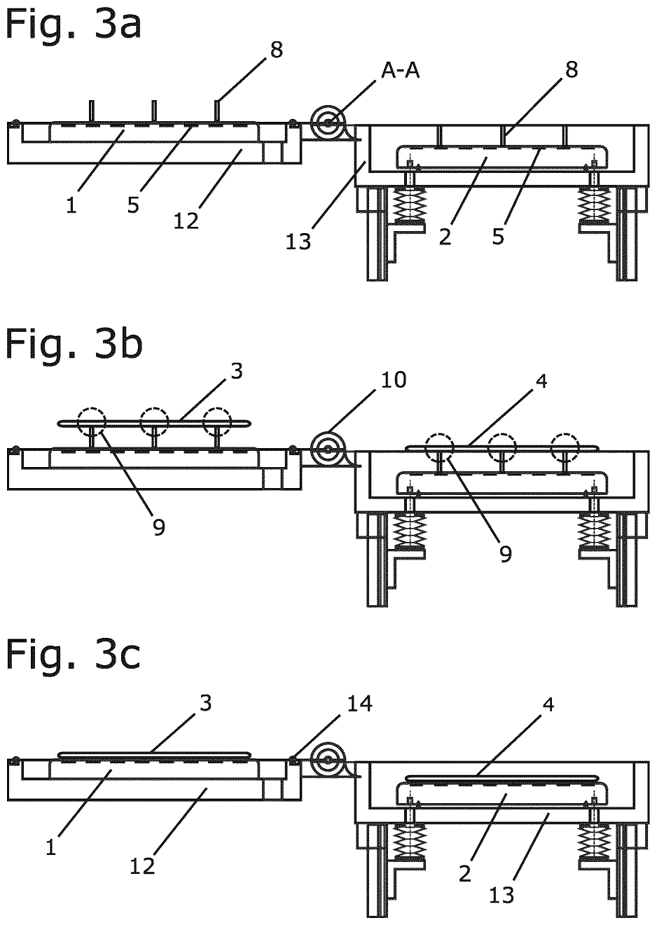

FIGS. 3a to 3c show a cross-sectional view of a first embodiment of the device with a mechanically constituted hinge 10 in the axis of symmetry or in swivelling axis A-A. The two chamber sections 12, 13, as shown in FIGS. 3a to 3c, are first opened. In a first process step according to FIG. 3a, loading pins 8 of first and second mounting device 1, 2 are located in the loading position. In a second process step according to FIG. 3b, first substrate 3 and second substrate 4 are loaded onto loading pins 8 of mounting devices 1, 2. The loading of the two substrates 3, 4 is carried out with an identical influence of gravity, i.e. both from above. The rear side of substrates 3, 4 is brought into contact with loading pins 8 on the holding surface of mounting device 1, 2 and fixed by electrostatic forces. Substrates 3, 4 are fixed with high positioning accuracy and with a high holding force. Electrodes are preferably embedded in mounting device 1, 2 and can be constituted unipolar or bipolar. The embodiment of the electrodes is symmetrical with respect to the axis of the two substrates 3, 4.

The mounting devices or substrate holders 1, 2 are positioned and loaded in such a way that both substrates 3, 4 are mounted in an identical manner on symmetrically constituted mounting devices 1, 2 before the contacting and before the bonding, so that the substrates are contacted and bonded with corresponding zones with a stress pattern 9. The regions with a stress pattern 9 arise for example due to the contact with loading pins 8 and due to the deformations of the wafers between loading pins 8 due to gravitation.

In third process step according to FIG. 3c, first substrate 3 and second substrate 4 are mounted on the mounting devices and fixed with fixing means 5.

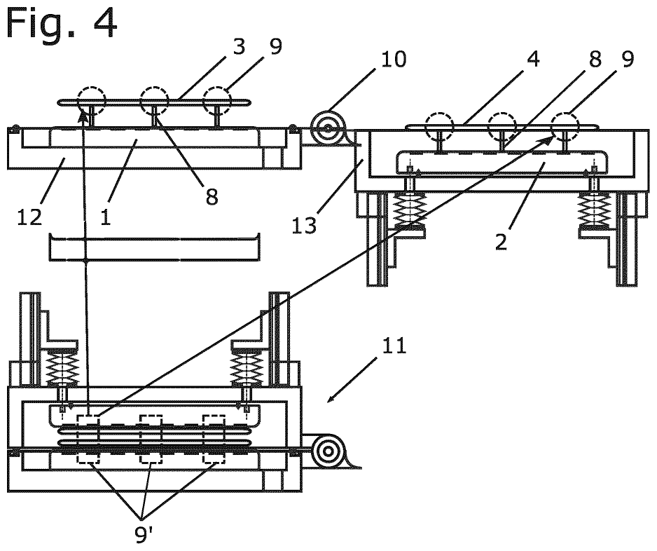

If substrate 3, 4 lies only on loading pins 8 as shown in FIG. 4, gravitation brings about a change with respect to a flat surface, wherein the corresponding regions of the first and second substrate with a stress pattern on account of the loading of the substrates on the symmetrically constituted loading pins are highlighted in the open swivelling device. This change in contact regions 9 is symmetrical for both substrates 3, 4 in bonding device 11, so that during bonding or after the bonding corresponding stress patterns are located in regions 9′ lying above one another. Identical stress patterns are thus present in the substrate stack about the bond interface.

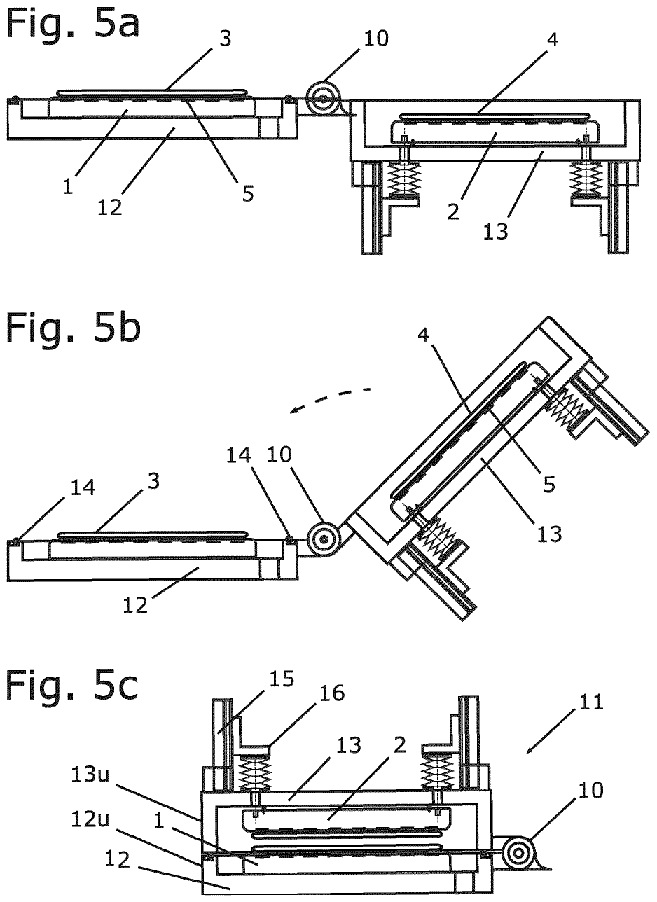

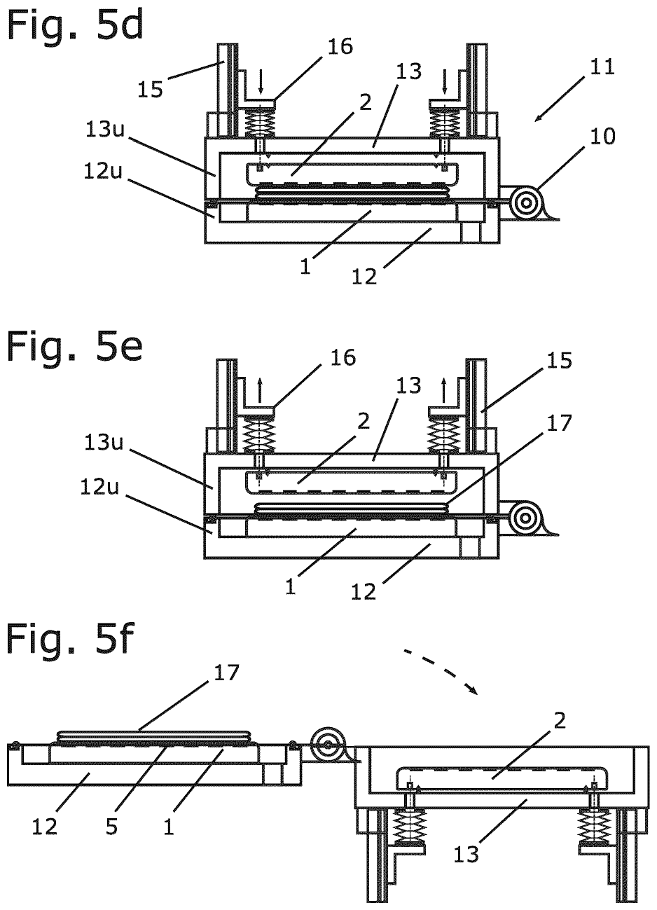

At least one of mounting devices 1, 2 is mounted in a swivelling manner. A possibility of moving second chamber section 13 relative to first chamber section 12 exists by carrying out a rotational movement between chamber sections 12, 13 via a swivelling link 10 according to FIG. 5b.

FIGS. 5a to 5f show the process steps on a first embodiment of the device and method for bonding 11, preferably permanent bonding, in particular fusion bonding, of a first substrate 3 with a second substrate 4, comprising:
a) a bonding chamber 11 consisting of a first chamber section 12 and a second chamber section 13,
b) mounting devices 1, 2 for mounting and fixing substrates 3, 4, wherein mounting devices 1, 2 are constituted for the approach and the contacting of the substrates.

The two chamber sections 12, 13, as shown in FIG. 5a, are first opened and substrates 3, 4 are fixed electrostatically. Electrodes for generating an electrostatic holding force for fixing the substrate are engaged in electrostatic mounting devices.

Ultra-flat electrostatic mounting devices 1, 2 have a holding surface constituted particularly flat, in order to press on substrates 3, 4 electrostatically and to ensure highly stable holding. The electrostatic attraction brings about a uniform distribution of the holding forces over the entire surface. The evenness of mounting device 1, 2 is better than the thickness variation and nanotopography of substrates 3, 4. Substrates 3, 4 can already have mechanical stresses due to preprocessing steps, which could cause a distortion in the non-fixed state.

After the loading and fixing of substrates 3, 4, the closing of bonding chamber 11 according to the embodiment according to FIG. 5b takes place by swivelling of second chamber section 13 about swivelling link 10. For this purpose, a motor drive, not represented, can be provided. After the swivelling of second chamber section 13, the peripheral wall 12u of first chamber section 12 lies according to FIG. 5c on the peripheral wall 13u of second chamber section 13. The sealing takes place by means of ring seal 14 on the upper side of peripheral wall 12u of first chamber section 12.

Bonding device 11 can advantageously be operated in a vacuum or also at ambient pressure under inert gas. Substrates 3, 4 are first adjusted with high precision for an exact alignment and are held separated during an evacuation process according to FIG. 5c. The alignment preferably takes place by means of alignment systems and with the aid of alignment marks. The adjustment and approach are known to the person skilled in the art and are not described in further detail.

In particular, contacting takes place after the alignment of the two substrates. In the next process step according to FIG. 5d, second, upper substrate 4 with mounting device 2 for bonding inside bonding chamber 11 is moved in a translatory manner onto first, lower substrate 3 with a movement device 15 and distance-changing means 16. Approach and adjustment are carried out in a controlled manner.

In order to be able to control the movement of second, upper substrate 4 precisely, at least one measuring device for measuring the position of second, upper substrate 4 is preferred in the embodiment of the device.

In the bonding process according to FIGS. 5a to 5f, substrates 3, 4 are laid flat upon one another. For the structures in the nm range and exact overlay, a reproducibility of the evenness of substrates 3, 4 to be bonded is very important. The holding force of ultra-flat electrostatic mounting devices 1, 2 with a holding surface constituted particularly flat enables a conformal planarisation of substrates 3, 4.

In a first preferred embodiment, after the contacting the two substrate 3, 4 each remain fixed to the first and second mounting device 1, 2 during the bonding. If both substrates 3, 4 remain fixed on the respective mounting device 1, 2 during the bonding, thickness variation (TTV, total thickness variation) and stress patterns of substrates 3, 4 have little influence on the bonding result. A parallel, spontaneous (1:1) bonding of the two substrates 3, 4 fixed on the mounting device is achieved, wherein no deformation of substrates 3, 4 takes place at the bonding front.

In a second less preferred embodiment, after the contacting the second, upper substrate 4 in particular remains fixed on mounting device 2 during the bonding. If second, upper substrate 4 remains fixed on mounting device 2 during the bonding, a smaller deformation of upper substrate 2 occurs at the bonding front, on account of the higher rigidity of the fixed substrate 2.

The basis of the idea is that both substrates 3, 4 are mounted identically on symmetrically constituted mounting devices 1, 2 before the contacting or the bonding, so that the stress at the substrate caused by the mounting and loading on mounting device 1, 2 is minimised and substrates 3, 4 are contacted or bonded with respectively corresponding stress patterns. As a result of the fixing of substrates 3, 4 during the bonding on the symmetrically constituted ultra-planar electrostatic mounting devices 1, 2, distortions in the bond interface are additionally minimised.

In an embodiment, mounting devices 1, 2 are constituted such that substrate 3, 4 can be heat-treated by heating means in particular in sections.

The application of pressure leads to an approach of the substrate surfaces at the interlayer along the contact surface.

The substrate can if necessary be pretreated before the bonding, in particular before the alignment. Examples of a pre-treatment are a plasma treatment or amorphisation of the at least one of the two substrate surfaces. Bonding chambers and process chambers for the amorphisation or plasma treatment can be part of an (evacuated) cluster system.

FIG. 5e shows a completed bonding process. Substrates 3, 4 are contacted over the entire surface and the bonding process is completed. After the upper fixing is switched off, the second, upper mounting device 2 is moved upwards inside bonding chamber 11 in a translatory manner with a movement device 15 and distance-changing means 16 back into the position according to FIG. 5c. Substrate stack 17 remains on first, lower mounting device 1.

As shown in FIG. 5f, the device for bonding 11 is opened again by a rotational movement between chamber sections 12, 13 via a swivelling link 10 of second chamber section 13 and substrate stack 17 can be removed after the release of the fixing of the first, lower mounting device. A release of bonded stack 17 from the substrate holders enables the substrate stress to be reduced in an identical manner. This relaxation process leads to a minimised residual stress.

At least one of mounting devices 1, 2 is mounted in a swivelling manner. Mounting devices 1, 2 can be rotated about an arbitrary axis. The rotation of one of the mounting devices with the substrate through 180° can thus not only take place as a rotational movement about a swivelling link according to FIG. 5a to 5e, but also a rotation about a mirror axis in the X-Y plane of mounting device 1, 2.

A further possibility consists in the fact that, after the rotation, a chamber section can be moved in a translatory manner towards the respective other chamber section or away from the latter. For example, the movement by means of a lifting cylinder is conceivable. Furthermore, lateral guides can also be provided. A combined rotational-translatory movement is also conceivable, for example via a four-link kinematic system.

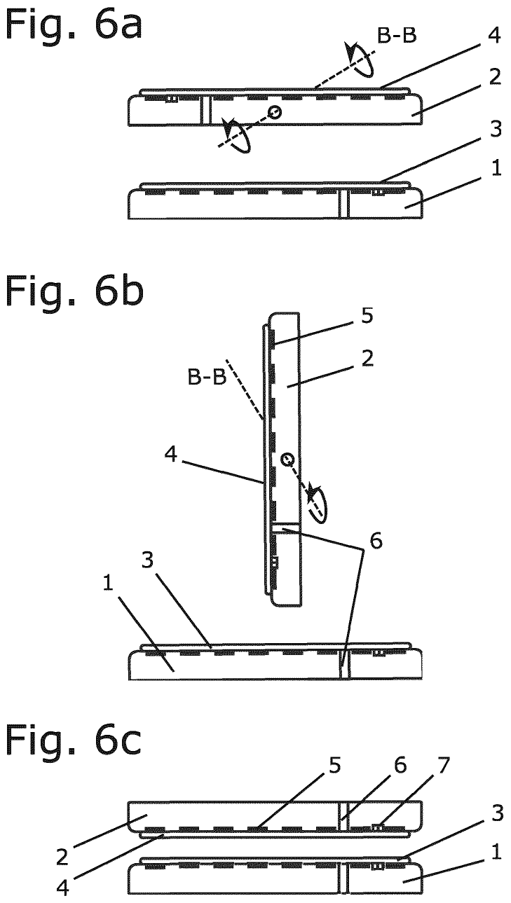

In a further embodiment according to FIGS. 6a to 6c, both mounting devices 1, 2 are located above one another, so that both substrates 3, 4 are loaded with an identical influence of gravity on the first and on the second mounting device 1, 2 according to FIG. 6a. After the fixing of substrates 3, 4, second, upper mounting device 2 with fixed substrate 4 is rotated upside down through 180° about its own rotation axis B-B according to FIG. 6b. After the rotation, the two mounting devices 1, 2 are facing one another mirror-symmetrically, so that all the features of mounting devices 1, 2 such as for example fixing elements 5, the openings for loading pins 6 and further surface features are positioned symmetrically.

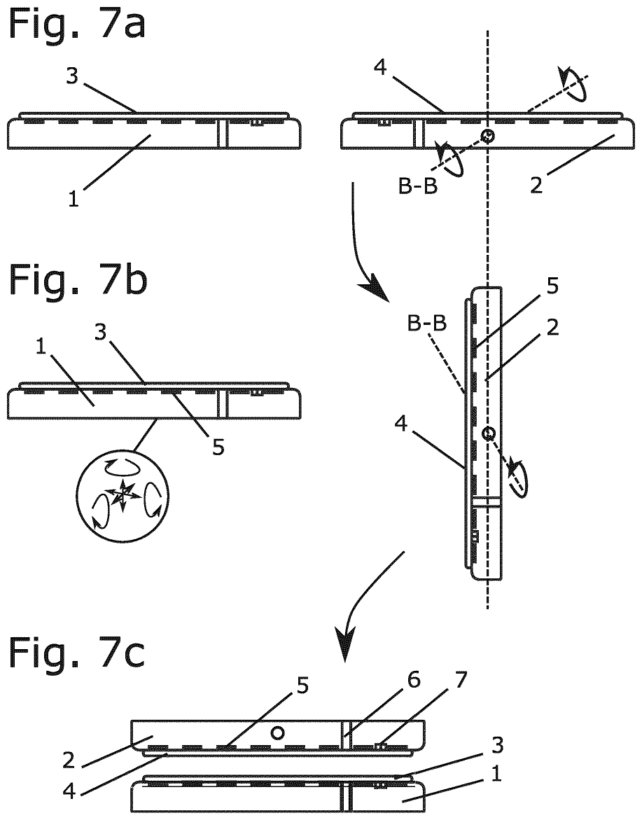

In a further embodiment according to FIGS. 7a to 7c, both mounting devices 1, 2 are located beside one another, so that, in this embodiment too, both substrates 3, 4 are loaded with an identical influence of gravity on the first and on the second mounting device 1, 2 according to FIG. 7 a. A combination of a rotational-translatory movement is carried out, so that first and second mounting device 1, 2 meet symmetrically.

The two mounting devices 1, 2 can be rotated about an arbitrary axis and then be brought into an adjusted symmetrical position by X/Y/Z translation (and rotation).

In a preferred embodiment, provision is made such that the substrate and/or mounting device 1, 2 can be moved in at least three degrees of freedom, preferably in at least four degrees of freedom, more preferably in at least five degrees of freedom, most preferably in all six degrees of freedom. This enables improved mobility of the substrate and/or the mounting device.

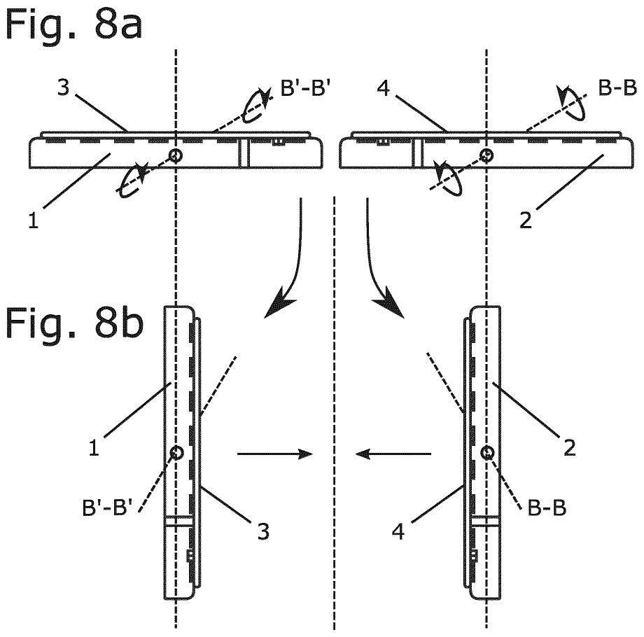

In a further embodiment according to FIGS. 8a and 8b, both mounting devices 1, 2 are located beside one another, so that, in this embodiment too, both substrates 3, 4 are loaded with an identical influence of gravity on first and on second mounting device 1, 2 according to FIG. 8a. For the bonding, both mounting devices 1, 2 with a substrate are rotated towards one another through 90°, so that they also meet symmetrically according to FIG. 8 b. The rotational movement of second mounting device 2 through 90° takes place via rotation axis B-B and the rotational movement of first mounting device 1 through 90° takes place via rotation axis B′-B′. After adjustment and approach, substrates 3, 4 are bonded over the whole surface in this vertical plane.

### LIST OF REFERENCE NUMBERS

1 First mounting device, first substrate holder
2 Second mounting device, second substrate holder
3 First substrate
4 Second substrate
5 Fixing element, first fixing means, second fixing means, fixing means
6 Opening for loading pins
7 Further feature of the mounting device
8 Loading pin
9,9′ Regions with the emergence of stress patterns during the wafer loading
10 Swivelling link, swivel axis
11 Device for bonding, bonding device
12 First chamber section
13 Second chamber section
12u, 13u Peripheral wall
14 Annular seal
15 Movement device (drive means)
16 Distance-changing means, approach means
17 Substrate stack
A-A Rotation axis
B-B, B′-B′ Rotation axis

1. A method for bonding substrates comprising:
providing a first substrate on a first substrate holder surface of a first substrate holder and a second substrate on a second substrate holder surface of a second substrate holder,
the first substrate on the first substrate holder by first fixing means and the second substrate on the second substrate holder by second fixing means in a loading state,
positioning the second substrate holder relative to the first substrate holder in a bonding position, so that the first substrate and the second substrate are facing one another with surfaces to be bonded, and
bonding the first substrate with the second substrate,
wherein in the loading state the first substrate holder surface and the second substrate holder surface are arranged at a same angle relative to a gravitational force,
wherein, in the loading state the first substrate holder surface and the second substrate holder surface are aligned in a same direction relative to the gravitational force, and
wherein, in the fixing of the first substrate and the second substrate by the first fixing means and the second fixing means, identical holding forces are exerted respectively on the first substrate and the second substrate, the identical holding forces being maintained during the bonding.

2. The method according to claim 1, wherein in the loading state the first substrate lies on the first substrate holder surface and the second substrate lies on the second substrate holder surface.

3. The method according claim 1, wherein the same angle is a vertical angle.

4. The method according claim 1, wherein, during the fixing in the loading state, the identical holding forces are provided at the first substrate and the second substrate each in a pattern corresponding to one another, so that the pattern of the holding forces is aligned in the bonding position.

5. The method according to claim 1, wherein the fixing of the first substrate and of the second substrate takes place simultaneously and within a same period.

6. The method according to claim 1 wherein the positioning comprises swivelling the second substrate about 180°.

7. The method according to claim 1, wherein the positioning comprises swivelling the first substrate holder and the second substrate holder towards one another each through 90°.

8. (canceled)

9. A device for bonding of substrates, comprising:
a first substrate holder with a first substrate holder surface,
first fixing means for fixing a first substrate on the first substrate holder surface,
a second substrate holder with a second substrate holder surface,
second fixing means for fixing a second substrate on the second substrate holder surface, and
c) positioning means j-for positioning the second substrate holder holder relative to the first substrate holder,
wherein the vice can be transferred into a loading state, in which the first substrate holder surface and the second substrate holder surface are arranged at same angle relative to e of gravity,
wherein in the loading state the first substrate holder surface and the second substrate holder surface are aligned in an identical direction relative to the force of gravity,
wherein the first fixing means and the second fixing means are designed to each provide identical holding forces for fixing in the loading state, and
wherein the first fixing means and the second fixing means are constituted to provide the identical holding forces at least until immediately after the bonding of the first substrate with the second substrate.

10. The according to claim 9, wherein the designed such that in the loading state the first substrate holder surface and the second substrate holder surface are arranged offset in parallel beside one another.

11. The device according to claim 9, wherein the second substrate holder is swivelled out of the loading state into a bonding position.

12. The device according to claim 9, wherein the positioning means comprises a swivelling link.

13. The according to claim 9, wherein the first fixing means and the second fixing means are electrostatic fixing means.

14. The device according to claim 11, wherein in the bonding position the first substrate holder and the second substrate holder constitute a bonding chamber.

15. (canceled)
